(19) United States
(12) Patent Application Publication
(10) Pub. No.: US 2015/0303162 A1
(43) Pub. Date: Oct. 22, 2015

(54) INTEGRATED CIRCUIT CHIP AND DISPLAY APPARATUS

(71) Applicants: BOE TECHNOLOGY GROUP CO., LTD., Beijing (CN); CHENGDU BOE OPTOELECTRONICS TECHNOLOGY CO., LTD., Chengdu, Sichuan (CN)

(72) Inventors: Junping BAO, Beijing (CN); Wei HE, Beijing (CN); Xinghua LI, Beijing (CN); Seung Yik PARK, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 14/407,345

(22) PCT Filed: Jun. 20, 2014
(86) PCT No.: PCT/CN2014/080460

§ 371 Date: Dec. 11, 2014

(30) Foreign Application Priority Data
Jan. 29, 2014 (CN) 201410043730.X

(51) Int. Cl. H01L 23/00; G02F 1/133

(52) U.S. Cl. CPC H01L 24/17; G02F 1/13306; H01L 2924/2064; H01L 2924/14; H01L 2224/1411; H01L 2224/1355; H01L 2224/16113; H01L 2224/16055; H01L 2224/1605

(57) ABSTRACT

Provided are an IC chip and a display apparatus. The IC chip (109) comprises several conductive metal sheets spaced from each other on one side of the IC chip, and conductive bumps (111) are formed on the conductive metal sheets. According to the present disclosure, since conductive bumps (111) are arranged on the conductive metal sheet of the IC chip (109), it is possible to use a non-conductive bonding layer such as NCF instead of ACF to bond the IC chip (109) to the display panel, and thus no metal particles would accumulate. As a result, the problem of short circuit or too large resistance will not occur. In addition, it is possible to reduce the production cost of the display apparatus by using NCF instead of ACF, facilitating industrialized manufacturing.

### TECHNICAL FIELD OF THE DISCLOSURE

The present disclosure relates to an integrated circuit (IC) chip and a display apparatus.

### BACKGROUND

In a connection between wires of a liquid crystal display (LCD) panel and an IC chip containing a driving circuit, the anisotropic conductive film (ACF) is usually used. The ACF has a characteristic of being electrically conductive in the Z axis direction but insulated in the XY plane, which can be used to realize connection of wires of fine microelectronic devices. The ACF consists of a polymer substrate and conductive particles uniformly distributed in the polymer substrate. The conductive particles can be polymer micro-balls coated with metal or metal particles. Currently, commonly used conductive particles are metal particles such as gold balls. With the enlarging market demand for the LCD apparatus year by year, the demand for the ACF as a main material for the interconnection between IC chips and LCD panels rapidly grows year by year, and its price is very high.

In recent years, electronic display technologies, such as LCD, electroluminescence technologies, touch screen technologies, and so on develop fast. One of the key technologies of the electronic display technologies is connection between the IC chip comprising a driving circuit and conductive patterns on the LCD panel. When using the ACF for package and connection, the metal particles are easy to accumulate, which causes poor conductive performance in the Z axis direction. In some areas, there are too few metal particles and thus the resistance is too high. However, in some other areas, there are too many metal particles, which extends conductive metal sheets in the IC, causing short circuit between adjacent conductive metal sheets to generate too large current and thus high temperature. It then deforms related electronic devices in the IC chip, thus affecting the quality and reliability of the display apparatus.

A normal bonding manner between the IC chip and the LCD panel is as shown in FIG. 2. An ACF comprising metal particles 102 and high polymer 103 is arranged between the IC chip 109 and the display panel connection area 106. The connection between them is realized by applying pressure through a device pressing head 110 in a bonding device. The main problem is that: an ACF which has high price is needed when bonding; during the bonding procedure, with the change in the pressure of the device pressing head, the heating temperature, the heating time and so on, the mechanical performance, the electrical performance and the reliability of the ACF interconnection change accordingly. It may cause low capture rate of gold balls in the ACF, severe extension of conductive metal sheets of the IC, and unreliable connection or wrong connection, thereby disturbing the normal displaying of the display apparatus.

### SUMMARY

At least one embodiment of the present disclosure is to avoid the drawbacks caused by bonding the IC chip and the display apparatus through the ACF in the known technical solutions.

According to one aspect of the present disclosure, there is provided an integrated circuit (IC) chip, wherein the IC chip comprises several conductive metal sheets spaced from each other on one side of the IC chip, and conductive bumps are formed on each of the conductive metal sheets.

Optionally, the shape of the conductive bump is cube, cuboid, frustum of cone, or frustum of pyramid.

Optionally, the height of the conductive bump is 3 μm˜5 μm, its width is 1 μm˜3 μm, and the distance between the conductive bumps is 1.0 μm˜3.0 μm.

Optionally, the surfaces of all the conductive bumps that are distant from the conductive metal sheet are aligned on the same level.

Optionally, the conductive bumps and the conductive metal sheet are molded integrally or respectively.

According to another aspect of the present disclosure, there is provided a display apparatus comprising a display panel and an IC chip as described in the above, and the display panel and the IC chip are electrically connected.

Optionally, the display panel is connected together with the side of the IC chip that has the conductive bumps through a non-conductive bonding layer.

Optionally, the non-conductive bonding layer is a no conductive film (NCF) layer.

Optionally, the NCF layer comprises a substrate film, a polymer bonding layer and a protection film that are arranged layer on layer.

Optionally, the substrate film and the protection film are formed by polyethylene terephthalate (PET), and the polymer bonding layer is formed by thermoplastic or thermosetting resin.

Optionally, a conductive pattern is formed on the edge area of the display panel, and the conductive bumps are electrically connected to the conductive pattern.

At least one embodiment of the present disclosure can achieve the following benefits that the conductive bumps arranged on the conductive metal sheet of the IC chip result in good conductivity in the Z axis direction between the IC chip and the display panel, while sufficient insulation can be ensured in the XY plane direction. Therefore, it is possible to use a non-conductive bonding layer such as NCF instead of ACF to realize bonding process of the IC chip, and thus no metal particles would accumulate. As a result, the problem of short circuit or too large resistance will not occur. In addition, it is possible to reduce the production cost of the display apparatus by using NCF instead of ACF, facilitating industrialized manufacturing.

### BRIEF DESCRIPTION OF THE DRAWINGS

In order to explain the known solutions or embodiments of the present disclosure more clearly, in the following, the drawings required in the description of the known solutions or the embodiments will be briefly introduced. Obviously, the drawings in the following description are only some embodiments of the present disclosure. For those skilled in the art, other drawings can be obtained based on these drawings without creative work.

FIG. 1 is a cross section of an ACF;

FIG. 2 is a schematic diagram illustrating normal bonding between an IC chip and a display panel;

FIG. 3 is a schematic diagram illustrating bonding between an IC chip and a display panel provided by an embodiment of the present disclosure;

FIG. 4a is a schematic partial plan view of an IC chip according to an embodiment of the present disclosure;

FIG. 4b is a schematic side view of FIG. 4a;

FIG. 5a is a schematic partial plan view of a first variant of the IC chip according to an embodiment of the present disclosure;

FIG. 5b is a schematic side view of FIG. 5a;

FIG. 6a is a schematic partial plan view of a second variant of the IC chip according to another embodiment of the present disclosure;

FIG. 6b is a schematic side view of FIG. 6a;

FIG. 7 is a schematic partial plan view of a third variant of the IC chip according to yet another embodiment of the present disclosure.

### DETAILED DESCRIPTION

In the following, clear and complete description will be made on technical solutions in embodiments of the present disclosure in connection with the drawings of the embodiments of the present disclosure. Obviously, the described embodiments are only part of embodiments of the present disclosure, but not all the embodiments. All other embodiments obtained by those skilled in the art based on the embodiments in the present disclosure without creative work fall in the protection scope of the present disclosure.

The embodiment provides an IC chip. As shown in FIG. 3, the IC chip 109 comprises several conductive metal sheets (not shown in the figure) spaced from each other on one side of the IC chip, and conductive bumps 111 are formed on the conductive metal sheets. The IC chip 109 usually comprises a driving chip and can also comprise other functional circuits. The conductive metal sheets are interfaces for electrically connecting the IC chip to other electrical elements, such as driving wires on the display panel.

Because the conductive bumps are arranged on the conductive metal sheet of the IC chip, when connecting with related electrical elements, good conductivity in the Z axis direction between the IC chip and the display panel can be achieved, while sufficient insulation can be ensured in the XY plane direction. Therefore, it is possible to use a non-conductive bonding layer such as NCF instead of ACF to realize the electrical connection of the IC chip to related electrical elements, and thus no metal particles would accumulate. As a result, the problem of short circuit or too large resistance will not occur. In addition, using NCF instead of ACF would not damage the circuit features of the IC chip, and can accelerate the electronic wire packaging or connection, and improve production efficiency. It is suitable for large scale and pipeline work. It can facilitate industrialized manufacturing and reduce the production cost.

Optionally, one conductive bump is formed on each conductive metal sheet. Further, the height of the conductive bump 111 is 3 μm˜5 μm, its width is 1 μm˜3 μm, the distance between the conductive bumps is 1.0 μm˜3.0 μm, and the surfaces of all the conductive bumps that are distant from the conductive metal sheet are aligned on the same level, so as to ensure good electrical conductivity between the IC chip and a related electrical element after they are bonded.

The conductive bumps and the conductive metal sheet can be molded integrally, i.e., the conductive bumps are directly formed on the conductive metal sheet when manufacturing the IC chip, one-time molded, or the conductive bumps are formed on the conductive metal sheet that have been molded. The conductive bumps and the conductive metal sheet can also be molded respectively, that is, when fabricating the IC chip, no conductive bump is formed on the conductive metal sheet, then the conductive bump structures are fabricated separately, and the conductive bumps are formed on the conductive metal sheet through related process. The conductive bump and the conductive metal sheet can be fabricated by the same or different conductive metal materials, which is not limited herein.

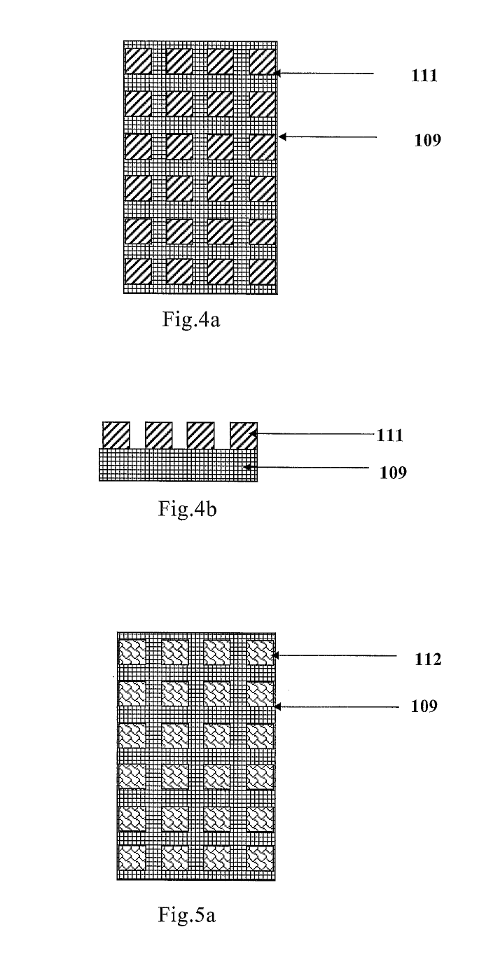

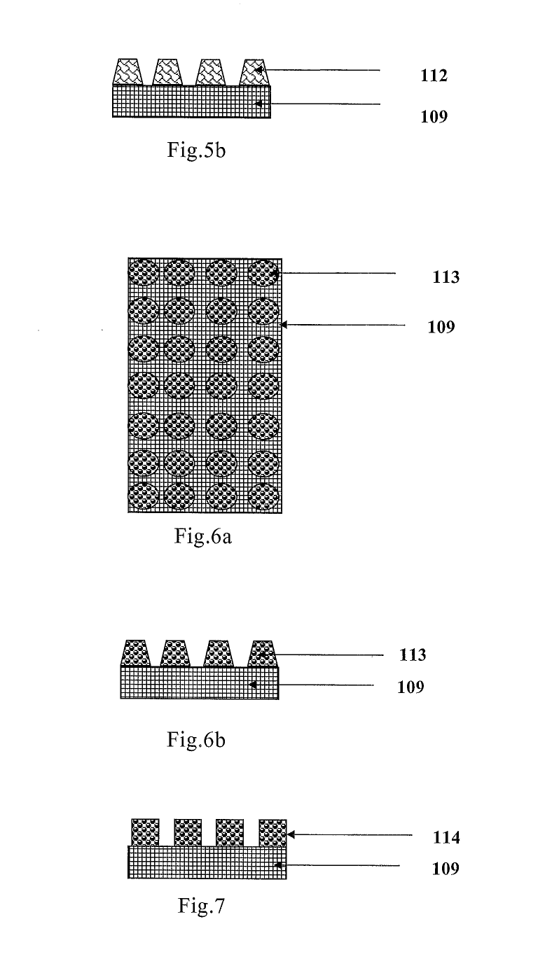

The conductive bump 111 on the conductive metal sheet of the IC chip 109 can designed as cuboid or cube, as shown in FIG. 4a and FIG. 4b. The conductive bump 111 can also be designed as frustum of pyramid 112, as shown in FIG. 5a and FIG. 5b. The conductive bump 111 can also be designed as frustum of cone 113, as shown in FIG. 6a and FIG. 6b. Alternatively, the conductive bump 111 can also be designed as cylinder 114, as shown in FIG. 7.

An embodiment of the present disclosure also provides a display apparatus comprising a display panel and an IC chip, wherein the display panel and the IC chip are electrically connected.

The IC chip is used to provide required electrical signals to the display apparatus, and the IC chip is usually connected to related driving wires in the display panel, for example, data lines, gate lines or driving circuits of the gate lines, and so on in the display panel. According to the display apparatus in the embodiment, since conductive bumps are arranged on the conductive metal sheet of the IC chip, when connecting with the display panel, good conductivity in the Z axis direction between the IC chip and the display panel can be achieved, while sufficient insulation can be ensured in the XY plane direction. Therefore, it is possible to use a non-conductive bonding layer such as NCF instead of ACF to realize the electrical connection of the IC chip to display panel, and thus no metal particles would accumulate. As a result, the problem of short circuit or too large resistance will not occur, and thus the quality of the display apparatus can be improved.

Further, as shown in FIG. 3, the display panel 106 can be connected together with the side of the IC chip 109 that has the conductive bumps 111 through a non-conductive bonding layer.

Optionally, the above non-conductive bonding layer can be a no conductive film (NCF) layer 108. As shown in FIG. 3, the display panel 106 is connected together with the side of the IC chip 109 that has the conductive bumps 111 through the NCF layer 108. The device pressing head 110 shown in the figure is not part of the display apparatus, but a device for applying pressure when bonding the IC chip 109 to the display panel 106. The IC chip 109 usually comprises a driving circuit, and can also comprise other functional circuits. Although the NCF layer is used for bonding in the embodiment, other non-conductive bonding materials can also be employed.

In the embodiment, it is possible to realize the electrical connection between the IC chip and the display panel by using NCF instead of currently commonly used ACF, which would not damage the circuit features of the IC chip, and can accelerate the electronic wire packaging or connection, and improve production efficiency. It is suitable for large scale and pipeline work. It can facilitate industrialized manufacturing and reduce the production cost.

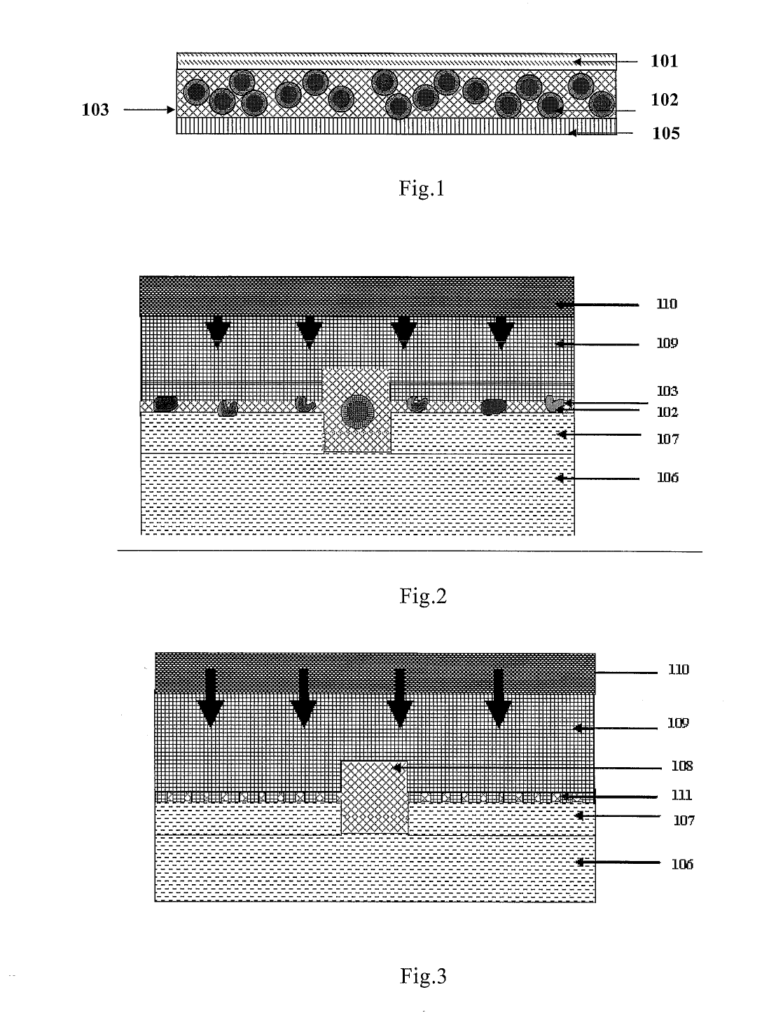

FIG. 1 is a cross section of a commonly used ACF, which comprises a protection film 101, high polymer 103 and a substrate film 105 that are arranged layer on layer. The high polymer 103 is doped with metal conductive particles 102.

Compared with FIG. 1, the NCF used in the present disclosure has similar structures to FIG. 1 except that no metal conductive particles 102 are needed in the NCF, other part of structures are the same as FIG. 1.

The above NCF layer 108 can comprise a substrate film, a polymer bonding layer and a protection film that are arranged layer on layer. The polymer bonding layer can be formed by thermoplastic or thermosetting resin, which has the bonding function. The protection film can be formed by transparent polyethylene terephthalate (PET) to protect the NCF from being contaminated. The substrate film can also be formed by transparent PET as a carrier of the polymer bonding layer. With the usage of NCF which does not contain the metal particles inside the ACF, stronger glutinosity can be achieved, and the bonding effect between the IC chip and the display panel can be enhanced. The connection is tight and electrical conductivity can be ensured. It is possible to avoid the short circuit between conductive metal sheets or between wires caused by metal conductive particle accumulation.

Optionally, in order to realize good electrical connection between the IC chip 109 and the display panel 106, as shown in FIG. 3, a conductive pattern 107 can be formed in the edge area of the display panel 106, for example, a conductive pattern formed by Indium Tin Oxide (ITO). The conductive pattern 107 is configured to connect to the internal wires of the display panel to realize electrical connection between the IC chip and the display panel.

Refer to FIG. 3, according to an embodiment of the present disclosure, when bonding the IC chip to the display panel, it is possible to first remove the protection film of the NCF by a conventional ACF bonding device, cut the NCF into a required length by a knife, bond the NCF onto the display panel 106 by heating and pressing, lightly bond the IC chip 109 on the NCF 108 without protection film after alignment, and then perform pressing by the device pressing head 110 to make an electrical connection between the conductive bumps 111 and the display 106 under high pressure.

The display apparatus in the embodiment can be a liquid crystal panel, an electronic paper, an OLED panel, a LCD TV, a LCD, a digital photo frame, a cell phone, a Tablet or any other product or part with display function.

The above embodiments are only for illustrating the present disclosure, but not limiting the present disclosure. Although the present disclosure is described in detail with reference to embodiments, those skilled in the art should understand that various combinations, modifications or equivalent replacements to the technical solutions of the present disclosure would not depart from the spirit and scope of the technical solutions of the present disclosure, which should be included in the scope of the claims of the present disclosure.

The present application claims the priority of Chinese Patent Application No. 201410043730.X filed on Jan. 29, 2014, the entire disclosed content of which is incorporated as part of the present invention by reference.

1-20. (canceled)

21: An IC chip, comprising several conductive metal sheets spaced from each other on one side of the IC chip, and conductive bumps are formed on each of the conductive metal sheets.

22: The IC chip according to claim 21, wherein the shape of the conductive bump is cube, cuboid, frustum of cone, frustum of pyramid or cylinder.

23: The IC chip according to claim 21, wherein the height of the conductive bump is 3 μm˜5 μm, its width is 1 μm˜3 μm, and the distance between the conductive bumps is 1.0 μm˜3.0 μm.

24: The IC chip according to claim 22, wherein the height of the conductive bump is 3 μm˜5 μm, its width is 1 μm˜3 μm, and the distance between the conductive bumps is 1.0 μm˜3.0 μm.

25: The IC chip according to claim 21, wherein the surfaces of all the conductive bumps that are distant from the conductive metal sheet are aligned on the same level.

26: The IC chip according to claim 22, wherein the surfaces of all the conductive bumps that are distant from the conductive metal sheet are aligned on the same level.

27: The IC chip according to claim 23, wherein the surfaces of all the conductive bumps that are distant from the conductive metal sheet are aligned on the same level.

28: The IC chip according to claim 24, wherein the surfaces of all the conductive bumps that are distant from the conductive metal sheet are aligned on the same level.

29: The IC chip according to claim 21, wherein the conductive bumps and the conductive metal sheet are molded integrally or respectively.

30: The IC chip according to claim 22, wherein the conductive bumps and the conductive metal sheet are molded integrally or respectively.

31: The IC chip according to claim 23, wherein the conductive bumps and the conductive metal sheet are molded integrally or respectively.

32: The IC chip according to claim 24, wherein the conductive bumps and the conductive metal sheet are molded integrally or respectively.

33: The IC chip according to claim 25, wherein the conductive bumps and the conductive metal sheet are molded integrally or respectively.

34: The IC chip according to claim 26, wherein the conductive bumps and the conductive metal sheet are molded integrally or respectively.

35: A display apparatus comprising a display panel, wherein the display apparatus further comprises an IC chip according to claim 21, and the display panel and the IC chip are electrically connected.

36: The display apparatus according to claim 35, wherein the display panel is connected together with the side of the IC chip that has the conductive bumps through a non-conductive bonding layer.

37: The display apparatus according to claim 36, wherein the non-conductive bonding layer is a no conductive film (NCF) layer.

38: The display apparatus according to claim 37, wherein the NCF layer comprises a substrate film, a polymer bonding layer and a protection film that are arranged layer on layer.

39: The display apparatus according to claim 38, wherein the substrate film and the protection film are formed by polyethylene terephthalate, and the polymer bonding layer is formed by thermoplastic or thermosetting resin.

40: The display apparatus according to claim 35, wherein a conductive pattern is formed on the edge area of the display panel, and the conductive bumps are electrically connected to the conductive pattern.
